(19) United States
(12) Patent Application Publication
(10) Pub. No.: US 2026/0246398 A1
(43) Pub. Date: Aug. 20, 2026

(54) BRAKE CONTROL

(71) Applicant: Texas Instruments Incorporated, Dallas, TX (US)

(72) Inventors: Stefan SCHIMONSKY, Muenchen (DE); Martin STAEBLER, Freising (DE); Kristen NOERGAARD-MOGENSEN, Freising (DE)

(73) Assignee: Texas Instruments Incorporated, Dallas, TX (US)

(21) Appl. No.: 19/286,370

(22) Filed: Jul. 31, 2025

Related U.S. Application Data
(60) Provisional application No. 63/760,041, filed on Feb. 18, 2025.

(51) Int. Cl. H02P 3/02; H03K 3/037; H03K 19/20

(52) U.S. Cl. CPC H02P 3/02; H03K 3/037; H03K 19/20

(57) ABSTRACT

An apparatus includes first and second switches, and a controller. The first switch has a first terminal coupled to a voltage input terminal, a second terminal coupled to a first inductor terminal, and a control terminal. The second switch has a first terminal coupled to a second inductor terminal, a second terminal coupled to a voltage output terminal, and a control terminal. The controller includes a modulator, an error amplifier, and a brake control circuit. The modulator has outputs coupled to the first switch's control terminal and the second switch's control terminal, and an input. The error amplifier has an output coupled to the modulator's input, and an input. The brake control circuit has an output coupled to the error amplifier's input, a first input coupled to a brake control terminal, a second input coupled to the voltage input terminal, and a third input coupled to the voltage output terminal.

### CROSS-REFERENCE TO RELATED APPLICATIONS

This application claims priority to U.S. Provisional Application No. 63/760,041, filed Feb. 18, 2025, entitled “Holding Brake Using a DC/DC Converter with Diagnostic Circuit,” which is hereby incorporated by reference in its entirety.

### BACKGROUND

Safe brake control (SBC) is a safety function that provides safe and reliable control of mechanical brakes in a variety of applications that use electric motors. SBC ensures that an electric motor can be stopped in the event of a system malfunction, a power loss, or other situation in which motor stop is desirable. SBC works with electromechanical brakes that are designed to engage when power is removed. For example, actuation of a relay or solenoid may disengage the brake, and removal of power from the relay may allow the brake to engage and stop the motor.

### SUMMARY

In one example, an apparatus includes a first switch, a second switch, and a controller. The first switch has a first terminal coupled to a voltage input terminal, a second terminal coupled to a first inductor terminal, and a control terminal. The second switch has a first terminal coupled to a second inductor terminal, a second terminal coupled to a voltage output terminal, and a control terminal. The controller includes a modulator, an error amplifier, and a brake control circuit. The modulator has a first output coupled to the control terminal of the first switch, a second output coupled to the control terminal of the second switch, and an input. The error amplifier has an output coupled to the input of the modulator, and an input. The brake control circuit has an output coupled to the input of the error amplifier, a first input coupled to a brake control terminal, a second input coupled to the voltage input terminal, and a third input coupled to the voltage output terminal.

In another example, an apparatus includes a high-side switch, a switching control circuit, and a logic gate. The high-side switch has a first terminal coupled to a voltage terminal, a second terminal, and a control terminal. The switching control circuit has a high-side switch output. The logic gate has a first input coupled to the high-side switch output, a second input coupled to a brake control terminal, and an output coupled to the control terminal of the high-side switch.

In a further example, a switching converter includes a switch, a brake control terminal, a controller, and a brake control circuit. The switch has a first terminal, a second terminal, and a control terminal. The switch is configured to conduct a current between the first terminal and the second terminal responsive to a control signal received at the control terminal. The brake control terminal is configured to receive a brake control signal. The controller has an input coupled to the brake control terminal, and an output coupled to the control terminal of the switch. The controller is configured to control the switch responsive to the brake control signal. The brake control circuit has a first input coupled to the second terminal of the switch, a second input coupled to the brake control terminal, and an output. The brake control circuit is configured to compare a voltage at the second terminal of the switch to a threshold responsive to the brake control signal, and provide a fault signal at the output of the brake control circuit. The fault signal indicates that the voltage at the second terminal of the switch exceeds the threshold responsive to the brake control signal.

### BRIEF DESCRIPTION OF THE DRAWINGS

FIG. 1 is a block diagram of an example system that includes a switching converter for safe brake control.

FIG. 2 is a schematic diagram of a first example switching converter that includes circuitry for verification of brake engagement.

FIGS. 3A and 3B are a schematic diagrams of additional example switching converters that include circuitry for verification of brake engagement.

FIG. 4 is a schematic diagram of an example operational transconductance amplifier circuit suitable for use in the brake control circuits of FIGS. 3A and 3B.

FIG. 5 is a schematic diagram of an example input comparator circuit suitable for use in the brake control circuits of FIGS. 3A and 3B.

FIG. 6 is a schematic diagram of an example output comparator circuit suitable for use in the brake control circuits of FIGS. 3A and 3B.

FIG. 7 is a schematic diagram of an example fault detection circuit suitable for use in the brake control circuits of FIGS. 3A and 3B.

FIG. 8 is a graph of example signals in the switching converter of FIG. 3A showing periodic testing with no fault.

FIG. 9 is a graph of example signals in the switching converter of FIG. 3A showing periodic testing with a fault.

FIG. 10 is a graph of example signals in the switching converter of FIG. 3A showing turn-off of the switching converter to engage the brake.

### DETAILED DESCRIPTION

In systems implementing safe brake control (SBC), current flows from a power supply to disengage a brake and allow motor rotation. If current flow ceases, the brake is engaged to halt motor rotation. During operation of the motor (e.g., while the motor is rotating), the capability of engaging the brake by ceasing the flow of current to the brake can be periodically tested by brake control circuitry to reduce the risk of brake failure. Some brake control circuits include a disconnect switch coupled between the power supply and the brake relay to control current flow to the brake. Such circuits may also include a blocking diode to inhibit the flow of reverse current from the brake relay, and a large capacitor to store charge for energizing the brake relay during testing. The disconnect switch, reverse blocking diode, and capacitor may increase system size and cost.

The switching converters described herein incorporate the brake control circuitry into the converter. The switching converters modulate control of the converter's switches to test brake engagement. Accordingly, the need for an additional switch, blocking diode, and capacitor is eliminated.

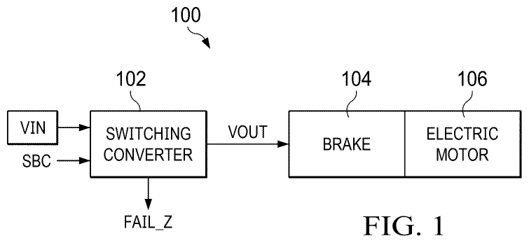

FIG. 1 is a block diagram of an example system 100 that includes safe brake control. The system 100 may be part of an industrial tool, a robot, or other device that may benefit from safe use of an electric motor. The system 100 includes a switching converter 102, a brake 104, and an electric motor 106. The brake 104 is mechanically coupled to the electric motor 106. For example, the brake 104 may be coupled to a shaft of the electric motor 106 so that the shaft can rotate if the brake is disengaged, and the shaft cannot rotate if the brake 104 is engaged. The brake 104 may include a relay or solenoid that is actuated to disengage the brake. If the relay is not actuated, then the brake 104 is engaged to halt rotation of the electric motor 106. An input of the brake 104 is coupled to the switching converter 102.

The switching converter 102 controls engagement and disengagement of the brake 104. The switching converter 102 may be a buck converter, buck-boost converter, or another type of switching converter. The switching converter 102 has an output at which a signal (labeled VOUT) is provided. The output of the switching converter 102 is coupled to the input of the brake 104. If VOUT provides sufficient voltage and current to actuate the brake 104, then the brake 104 is disengaged from the electric motor 106, otherwise the brake 104 is engaged to halt the electric motor 106.

The switching converter 102 has an input at which a brake control signal (SBC) is received. SBC may be provided by a microcontroller or other circuit that verifies safe operation of the brake 104. The switching converter 102 may engage or disengage the brake 104 responsive to SBC. If SBC has a first state (e.g., a logic high), then the switching converter 102 provides VOUT with sufficient voltage and current to actuate the brake 104, and the brake 104 is disengaged. If SBC has a second state (e.g., a logic low), then the switching converter 102 may be disabled, and provides VOUT with insufficient voltage and current to disengage the brake 104.

During operation of the electric motor 106 (during rotation of the electric motor 106), the switching converter 102 is, responsive to and based on VIN, providing VOUT with voltage and current sufficient to disengage the brake 104. SBC may periodically transition from the first state to the second state (for a test time) to test operation of the switching converter 102. That is, to verify that the switching converter 102 can discontinue the flow of current to the brake 104 responsive to SBC. The switching converter 102 may compare one or more voltages generated in the switching converter 102 to thresholds to determine whether the switching converter 102 can reduce the current flowing to the brake 104, and engage the brake 104 responsive to SBC. The switching converter 102 has an output at which the switching converter 102 provides a fault signal (FAIL_Z). The switching converter 102 may provide FAIL_Z with a first state (e.g., a logic high) if the comparisons indicate that switching converter 102 can provide VOUT suitable to engage the brake 104. The switching converter 102 may provide FAIL_Z with a second state (e.g., a logic low) if the comparisons indicate that switching converter 102 cannot provide VOUT suitable to engage the brake 104. FAIL_Z may be provided to a microcontroller or other circuit or other circuit that verifies safe operation of the brake 104. Accordingly, the switching converter 102 can test its operation to ensure that the brake 104 will be engaged based on SBC.

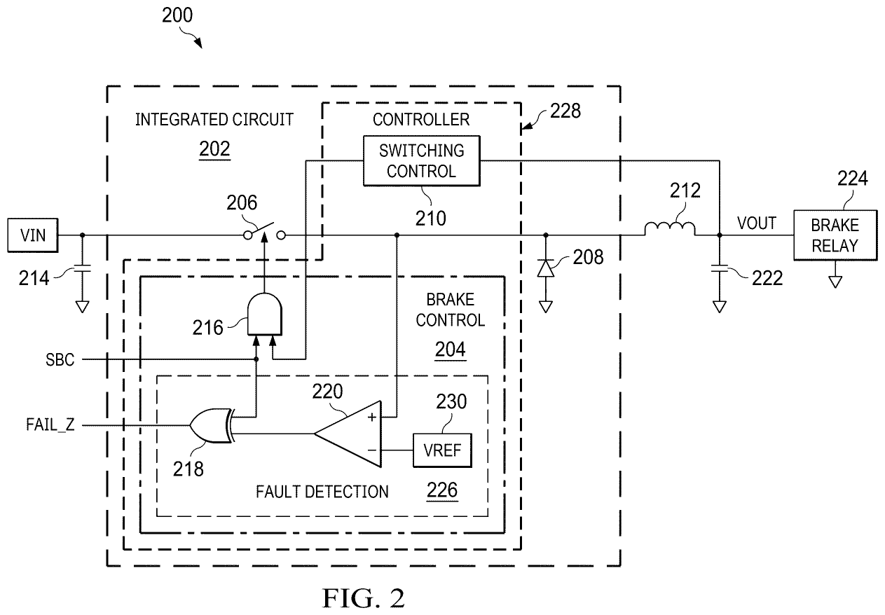

FIG. 2 is a schematic diagram of a first example switching converter 200 that provides verification of brake engagement. Examples of the switching converter 200 may be used to provide safe brake control in a variety of functional safety applications, including industrial robots, humanoid robots, collaborative robots, surgical robots, autonomous guided vehicles, factory automation, servo drives, etc. The switching converter 200 includes a high-side switch 206, a low-side switch 208, and a controller 228. The high-side switch 206, the low-side switch 208, and the controller 228 may be provided in an integrated circuit 202 in some examples. In other examples, the controller 228 is included on a separate integrated circuit than the high-side switch 208 and the low-side switch 208. An input voltage is received at a voltage input terminal VIN. The high-side switch 206 has a first terminal coupled to VIN, a second terminal coupled to the low-side switch 208, and a control terminal coupled to the controller 228. The high-side switch 206 may be an N-channel field effect transistor (NFET), or a P-channel field effect transistor (PFET) in some examples. The low-side switch 208 has a first terminal coupled to the second terminal of the high-side switch 206, and a second terminal coupled to a reference terminal (e.g., ground). While the low-side switch 208 is illustrated as a diode in FIG. 2, the low-side switch 208 may be a transistor in some examples of the switching converter 200. The low-side switch 208 provides a path for current flow when the inductor 212 is discharging (e.g., when the high-side switch 206 is open).

A capacitor 214 has a first terminal coupled to the first terminal of the high-side switch 206, and a second terminal coupled to the reference terminal. The capacitor 214 filters the voltage received at VIN. An inductor 212 has a first terminal coupled to the second terminal of the high-side switch 206, and a second terminal. A capacitor 222 has a first terminal coupled to the second terminal of the inductor 212, and a second terminal coupled to the reference terminal. The capacitor 222 filters the voltage provided at VOUT. A brake relay 224 coupled to the second terminal of the inductor 212 is shown for reference.

The controller 228 includes a brake control circuit 204, and a switching control circuit 210. The brake control circuit 204 includes a logic gate 216 and a fault detection circuit 226. The switching control circuit 210, which includes suitable analog and digital circuitry, provides a switching control signal (e.g., a pulse width modulation signal) that opens and closes the high-side switch 206 to charge and discharge the inductor 212 as needed to maintain a desired output voltage at a voltage output terminal VOUT, to which the second terminal of the inductor 212 is coupled. The switching control circuit 210 has an input coupled to the second terminal of the inductor 212, and an output, at which the switching control signal is provided, coupled to the logic gate 216.

The logic gate 216 may be an AND gate in some examples. The logic gate 216 may be implemented by any logic circuit performing the functionality of the AND gate 216 with respect to the overall function of the brake control circuit 204. The logic gate 216 has a first input coupled to the output of the switching control circuit 210, and a second input coupled to an SBC terminal. The logic gate 216 has an output coupled to the control terminal of the high-side switch 206. The SBC terminal may be an input terminal of the integrated circuit 202 for receiving SBC. If SBC has a first state (e.g., a logic high state), then the switch control signal is provided at the output of the logic gate 216 and at the control terminal of the high-side switch 206. If SBC has a second state (e.g., a logic low state), then a logic low voltage is provided at the output of the logic gate 216, and the control terminal of the high-side switch 206. Accordingly, if SBC is a logic low, the high-side switch 206 is open, and the voltage at the second terminal of the high-side switch 206 is reduced.

The fault detection circuit 226 detects a fault in the switching converter 200 responsive to SBC. For example, if the voltage at the second terminal of the high-side switch 206 remains above a threshold while SBC is a logic low state, then the fault detection circuit 226 provides the fault signal (FAIL_Z) with a state indicating that the switching converter 200 may be unable to engage the brake controlled by the brake relay 224. The fault detection circuit 226 includes a logic gate 218 and a comparator 220. The comparator 220 has a first input coupled to the second terminal of the high-side switch 206, and a second input coupled to a voltage reference circuit 230. The comparator 220 compares the voltage at the second terminal of the high-side switch 206 to a reference voltage provided by the voltage reference circuit 230. The logic gate 218 may be an EXCLUSIVE-OR (XOR) gate in some examples. The logic gate 216 may be implemented by any logic circuit performing the functionality of the XOR gate 218 with respect to the overall function of the fault detection circuit 226. If SBC has a logic low state, and the voltage at the second terminal of the high-side switch 206 exceeds the reference voltage, then the logic gate 218 may provide FAIL_Z with a logic low state, indicating that the switching converter 200 is unable to engage the brake controlled by the brake relay 224.

As described, the switching converter 200 provides verification of safe brake control without use of an external switch, a blocking diode, or a large energy storage capacitor.

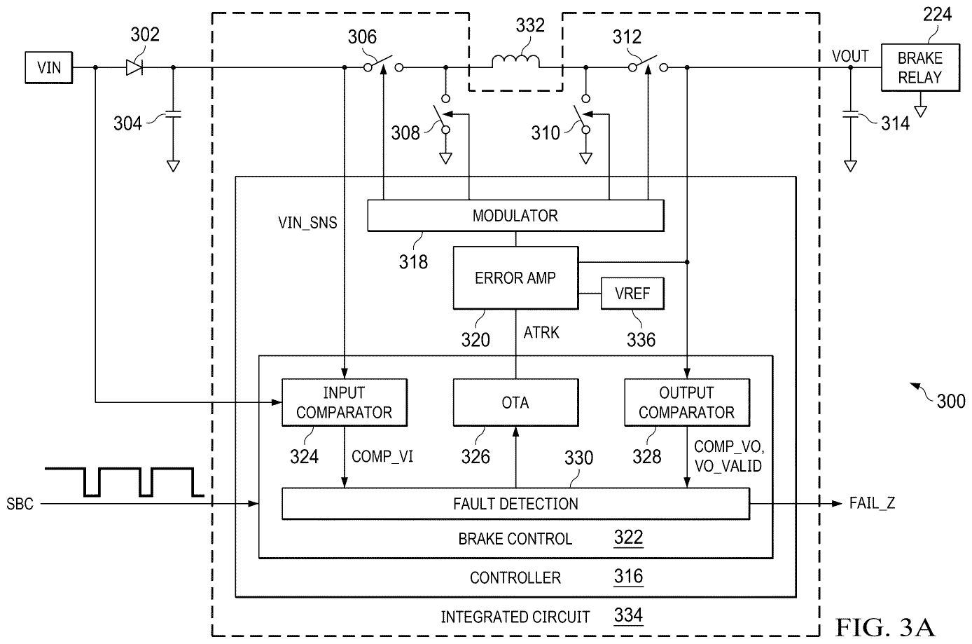

FIG. 3A is a schematic diagram of a second example switching converter 300 that provides verification of brake engagement. Examples of the switching converter 300 may be used to provide safe brake control in a variety of functional safety applications, including industrial robots, humanoid robots, collaborative robots, surgical robots, autonomous guided vehicles, factory automation, servo drives, etc. The switching converter 300 includes switches 306, 308, 310, and 312, and a controller 316. The switches 306, 308, 310, and 312, and the controller 316 may be provided in an integrated circuit 334 in some examples. In other examples, the controller 316 is included on a separate integrated circuit than the switches 306, 308, 310, and 312. In other examples, the brake control circuit 322 is included on a separate integrated circuit than the other elements of the controller 316 and the switches 306, 308, 310, and 312. The switches 306 and 312 may be NFETs or PFETs. The switches 308 and 310 may be NFETs. The switch 306 has a first terminal coupled to a voltage input terminal (VIN) via the diode 302. The diode 302 blocks the flow of current from the capacitor 304 to VIN. The capacitor 304 filters the voltage provided to the first terminal of the switch 306. The switch 306 has a second terminal coupled to a first inductor terminal. The switch 306 has a control terminal coupled to the controller 316. A capacitor 304 may be coupled between the first terminal of the switch 306 and a reference terminal (e.g., ground). The switch 312 has a first terminal coupled to a second inductor terminal, and a second terminal coupled to a voltage output terminal (VOUT). The switch 312 has a control terminal coupled to the controller 316. A capacitor 314 may be coupled between the second terminal of the switch 312 and the reference terminal. The capacitor 314 filters the voltage provided at VOUT. An inductor 332 may be coupled between the first inductor terminal and the second inductor terminal. The inductor 332 stores energy that is released through the switch 312 to provide the voltage at VOUT.

The switch 308 has a first terminal coupled to the second terminal of the switch 306, and a second terminal coupled to the reference terminal. The switch 308 has a control terminal coupled to the controller 316. The switch 310 has a first terminal coupled to the first terminal of the switch 312, and a second terminal coupled to the reference terminal. The switch 310 has a control terminal coupled to the controller 316.

The controller 316 controls switching of the switches 306, 308, 310, and 312 to provide a desired voltage at VOUT. For example, the controller 316 may control the switches 306, 308, 310, and 312 to step-down or step-up the voltage at VOUT relative to the voltage at VIN. The controller 316 includes a modulator 318, an error amplifier 320, and a brake control circuit 322. The modulator 318 provides switching control signals to the switches 306, 308, 310, and 312. For example, the modulator 318 may include pulse width modulation circuitry that generates the switching control signals. The modulator 318 has a first, second, third, and fourth outputs at which the switching control signals are provided. The first, second, third, and fourth outputs of the controller 316 are respectively coupled to the control terminals of the switches 306, 308, 310, and 312. The modulator 318 has an input coupled to the error amplifier 320. The error amplifier 320 provides an error signal that the modulator 318 uses to generate the switch control signals. The error signal may represent a difference in the voltage at VOUT (or a voltage derived from VOUT, e.g., using a voltage divider circuit) and a desired output voltage of the switching converter 300. The error amplifier 320 has an output coupled to the input of the modulator 318, a first input coupled to VOUT, a second input coupled to the brake control circuit 322, and a third input (e.g., also referred to as a voltage reference input or a reference input) coupled to a voltage reference circuit 336. The voltage reference circuit 336 is included in the controller 316 in some examples. In other examples, the voltage reference circuit 336 is not on the controller 316 nor on the integrated circuit 334.

The brake control circuit 322 verifies that the switching converter 300 can deenergize the brake relay 224 responsive to SBC. The brake control circuit 322 has an output coupled to the second input of the error amplifier 320. The brake control circuit 322 provides a signal ATRK at the output for use by the error amplifier 320. The error amplifier 320 may sum ATRK and a reference voltage provided by the voltage reference circuit 336, and provide the error signal as a difference of the summed signal and the voltage at VOUT.

The brake control circuit 322 includes an operational transconductance amplifier (OTA) circuit 326, an input comparator circuit 324, and an output comparator circuit 328, and a fault detection circuit 330. The OTA circuit 326 generates ATRK based on SBC. Responsive to ATRK, the controller 316 causes a small change in the voltage at VOUT. The input comparator circuit 324 compares the voltage at the anode of the diode 302 to the voltage at the cathode of the diode 302 to assess the operation of the switch 306. The input comparator circuit 324 provides a result of the comparison to the as an output signal COMP_VI. In an example, the output comparator circuit 328 compares the voltage at VOUT to multiple thresholds (or compares multiple voltages derived from the voltage at VOUT to a threshold) to assess the operation of the switch 312. The output comparator circuit 328 provides results of the comparisons as output signals COMP_VO and VO_VALID. The fault detection circuit 330 determines whether the switching converter 300 is able to deenergize the brake relay 224 based on COMP_VI, COMP_VO, and VO_VALID. The fault detection circuit 330 generates a fault signal (FAIL_Z) that indicates whether the switching converter 300 is able to deenergize the brake relay 224, and engage the brake, based on COMP_VI, COMP_VO, and VO_VALID. The fault detection circuit 330 may have an output or a fault terminal at which FAIL_Z is provided.

As described, the switching converter 300 provides verification of safe brake control without use of an external switch, a blocking diode, or a large energy storage capacitor.

FIG. 3B is a schematic diagram of a second example switching converter 350 that provides verification of brake engagement. The switching converter 350 is similar to the switching converter 300. The switching converter 350 differs from the switching converter 300 in that in the switching converter 350, ATRK is combined with the voltage at VOUT (e.g., using a voltage summing network (not shown)) to generate a signal provided at the second input of the error amplifier 320. A reference voltage is provided at the first input of the error amplifier 320. The voltage reference circuit 336 may provide the reference voltage. The error amplifier 320 may provide the error signal as a difference of the reference voltage and the combined ATRK and voltage at VOUT. Accordingly, the switching converter 350 differs from the switching converter 300 in the way ATRK is provided to the error amplifier 320. Other description of the switching converter 300 provided herein is applicable to the switching converter 350.

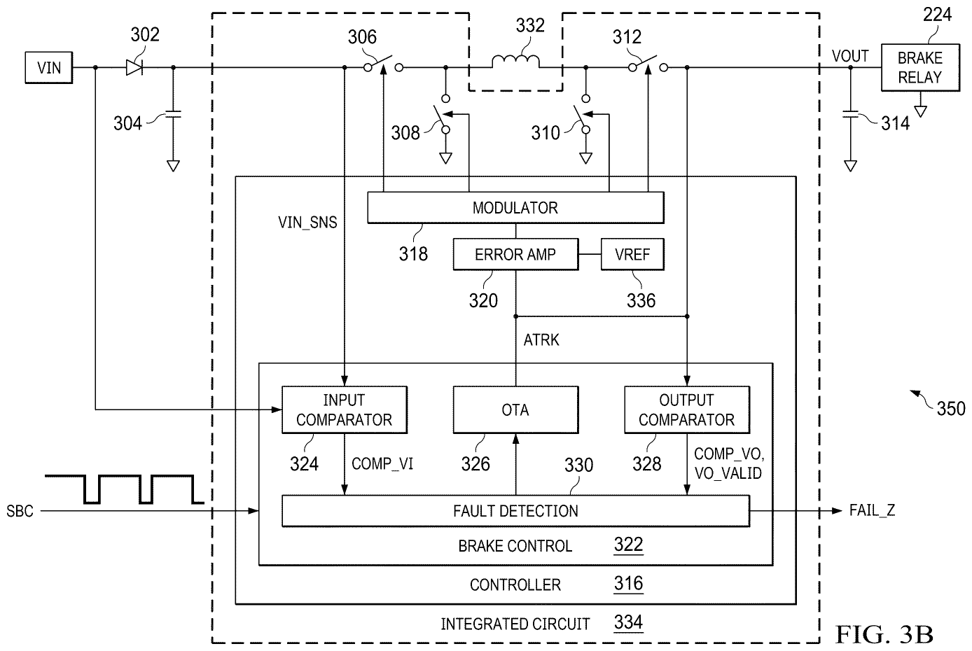

FIG. 4 is a schematic diagram of an example OTA circuit 326 suitable for use in the brake control circuit 322. The OTA circuit 326 includes a transconductance amplifier 402, a buffer circuit 408, voltage sources 404, 406, 426, and 428, resistors 412 and 414, capacitors 410 and 416, diodes 418 and 420, a switch 422, and a pulse generation circuit 424. The transconductance amplifier 402 has a first input (e.g., a non-inverting input) coupled to the SBC terminal, and a second input coupled to a first terminal of the voltage source 406. A second terminal of the voltage source 406 is coupled to the reference terminal.

A current input of the transconductance amplifier 402 is coupled to a first terminal of the voltage source 404. A second terminal of the voltage source 404 is coupled to the reference terminal. A current output of the transconductance amplifier 402 is coupled to the output of the OTA circuit 326 via the resistor 412. The resistor 412 has a first terminal coupled to the current output of the transconductance amplifier 402, and a second terminal coupled to the output of the OTA circuit 326, at which ATRK is provided. The transconductance amplifier 402 modulates the current provided at the current output of the transconductance amplifier 402 based on the voltage of the signal at SBC. The voltage provided by the 406 sets a threshold for the transconductance amplifier 402. The threshold may be one-half the amplitude of the signal at SBC.

The buffer circuit 408 has an input coupled to the SBC terminal, and an output coupled to the capacitor 410. The capacitor 410 may provide high-pass filtering of the signal at SBCA first terminal of the capacitor 410 is coupled to the output of the buffer circuit 408, and a second terminal of the capacitor 410 is coupled to the output of the OTA circuit 326 via the resistor 414. The resistor 414 has a first terminal coupled to the output of the OTA circuit 326, and a second terminal coupled to the second terminal of the capacitor 410. The capacitor 416 is coupled between the first terminal of the resistor 414 and the reference terminal. The capacitor 416 has a first terminal coupled to the first terminal of the resistor 414 and a second terminal coupled to the reference terminal. The capacitor 416 is charged by the current provided by the transconductance amplifier 402 and the buffer circuit 408.

The diodes 418 and 420, the voltage sources 426 and 428, the switch 422, and the 424 provide clamping of the voltage of ATRK. The diode 418 has a cathode coupled to the output of the OTA circuit 326, and an anode coupled to the voltage source 428. The voltage source 428 has a first terminal coupled to the anode of the diode 418, and a second terminal coupled to the reference terminal. The diode 420 has an anode coupled to the cathode of the diode 418, and a cathode coupled to the voltage source 426. The diode 420 has a first terminal coupled to the cathode of the diode 420, and a second terminal coupled to the switch 422. The switch 422 has a first terminal coupled to the second terminal of the voltage source 426, a second terminal coupled to the reference terminal, and a control terminal coupled to the pulse generation circuit 424. The pulse generation circuit 424 has an output coupled to the control terminal of the switch 422.

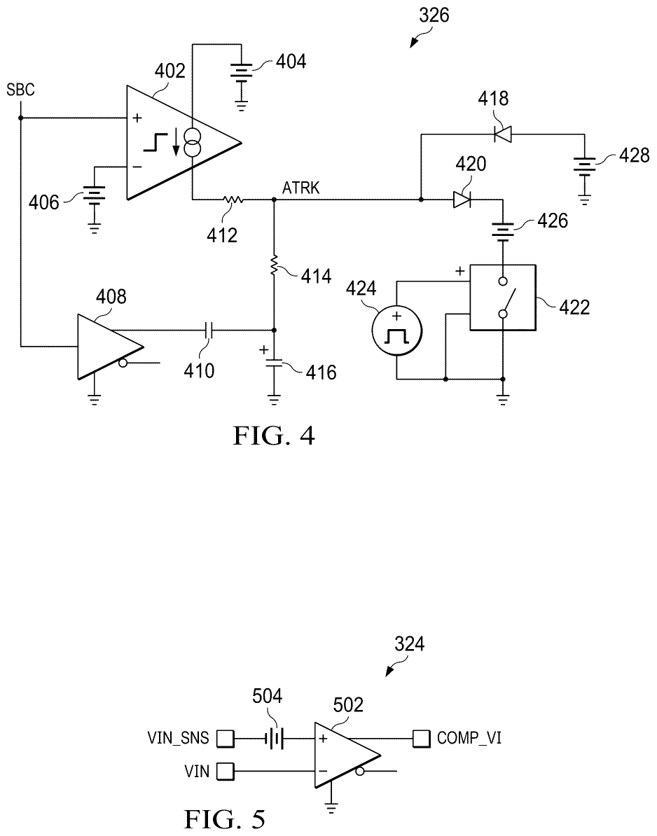

FIG. 5 is a schematic diagram of an example input comparator circuit 324 suitable for use in the brake control circuit 322. The input comparator circuit 324 includes a comparator 502 and a voltage source 504. The comparator 502 has a first terminal (e.g., a non-inverting terminal) coupled to a first terminal of the voltage source 504. A second terminal of the voltage source 504 is coupled to the first terminal of the switch 306. The comparator 502 has a second terminal (e.g., an inverting terminal) coupled to VIN. Accordingly, the comparator 502 compares the voltage VIN to the voltage at the first terminal of the switch 306 (with a voltage offset provided by the voltage source 504), and provides a result of the comparison as signal COMP_VI at an output of the comparator 502.

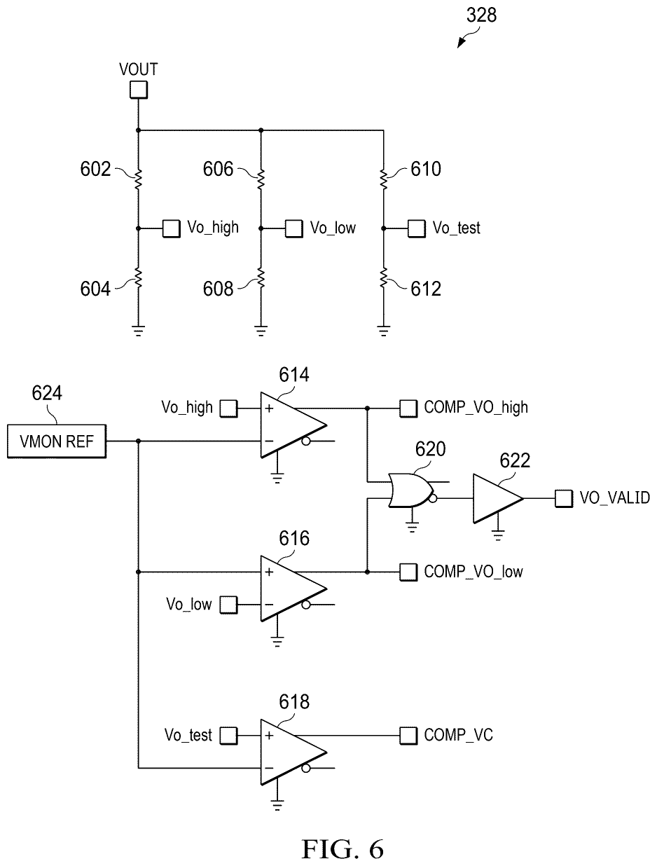

FIG. 6 is a schematic diagram of an example output comparator circuit 328 suitable for use in the brake control circuit 322. The output comparator circuit 328 includes resistors 602, 604, 606, 608, 610, and 612, comparators 614, 616, and 618, logic gate 620, buffer 622, and voltage reference circuit 624. The resistors 602 and 604 are coupled as a first voltage divider. A first terminal of the resistor 602 is coupled to VOUT, and a second terminal of the resistor 602 is coupled to a first terminal of the resistor 604. A second terminal of the resistor 604 is coupled to the reference terminal. A signal VO_HIGH is provided at the first terminal of the resistor 604.

The resistors 606 and 608 are coupled as a second voltage divider. A first terminal of the resistor 606 is coupled to VOUT, and a second terminal of the resistor 606 is coupled to a first terminal of the resistor 608. A second terminal of the resistor 608 is coupled to the reference terminal. A signal VO_LOW is provided at the first terminal of the resistor 608.

The resistors 610 and 612 are coupled as a third voltage divider. A first terminal of the resistor 610 is coupled to VOUT, and a second terminal of the resistor 610 is coupled to a first terminal of the resistor 612. A second terminal of the resistor 612 is coupled to the reference terminal. A signal VO_TEST is provided at the first terminal of the resistor 612.

The comparators 614, 616, and 618 compare VO_HIGH, VO_LOW, and VO_TEST to a reference voltage provided by the voltage reference circuit 624. The comparator 618 has a first input (e.g., a non-inverting input) coupled to the first terminal of the resistor 612 for receipt of VO_TEST, and a second input (e.g., an inverting input) coupled to the output of the voltage reference circuit 624. The comparator 618 compares VO_TEST to the reference voltage provided by the voltage reference circuit 624, and provides a signal COMP_VO at an output of the comparator 618. COMP_VO indicates whether VO_TEST exceeds the reference voltage.

The comparator 616 has a first input (e.g., an inverting input) coupled to the first terminal of the resistor 608 for receipt of VO_LOW, and a second input (e.g., a non-inverting input) coupled to the output of the voltage reference circuit 624. The comparator 616 compares VO_LOW to the reference voltage provided by the voltage reference circuit 624, and provides a signal COMP_VO_LOW at an output of the comparator 616. COMP_VO_LOW indicates whether VO_LOW is less than the reference voltage.

The comparator 614 has a first input (e.g., a non-inverting input) coupled to the first terminal of the resistor 604 for receipt of VO_HIGH, and a second input (e.g., an inverting input) coupled to the output of the voltage reference circuit 624. The comparator 614 compares VO_HIGH to the reference voltage provided by the voltage reference circuit 624, and provides a signal COMP_VO_HIGH at an output of the comparator 614. COMP_VO_HIGH indicates whether VO_HIGH exceeds the reference voltage.

The logic gate 620 combines the output signals of the comparators 614 and 616. The logic gate 620 may be a NOR gate. The logic gate 620 has a first input coupled to the output of the comparator 614, and a second input coupled to the output of the comparator 616. The logic gate 620 has an output, at which an output signal indicating whether the voltage at VOUT is within a selected range is provided. The output of the logic gate 620 is coupled to an input of the buffer 622. The buffer 622 has an output at which a signal VO_VALID is provided. VO_VALID has a first state (e.g., a logic high) if the voltage at VOUT is within a selected range, and has a second state (e.g., a logic low) if the voltage at VOUT is not within the selected range.

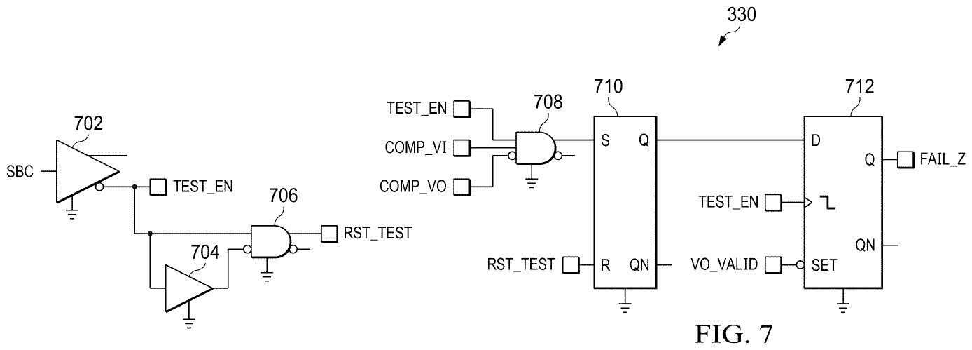

FIG. 7 is a schematic diagram of an example fault detection circuit 330 suitable for use in the brake control circuit 322. The fault detection circuit 330 provides a fault signal based on the comparison result signals provided by the input comparator circuit 324 and the output comparator circuit 328. The fault detection circuit 330 includes an inverter 702, a buffer 704, logic gates 706 and 708, and flip-flops 710 and 712. The inverter 702 has an input coupled to the SBC terminal for receipt of SBC. The inverter 702 has an output at which a signal TEST_EN is provided. TEST_EN is an inverted version of SBC.

The buffer 704 and the logic gate 706 are coupled to form a monostable circuit. The buffer 704 has an input coupled to the output of the inverter 702, and an output coupled to the logic gate 706. The buffer 704 provides a propagation delay used to generate a pulse at the rising edge of TEST_EN (the trailing edge of SBC). The logic gate 706 has a first input coupled to the output of the inverter 702, and a second input coupled to the output of the buffer 704. The logic gate 706 has an output at which a signal RST_TEST is provided. RST_TEST is a pulse at the trailing edge of SBC.

The logic gate 708 combines the TEST_EN, COMP_VI, and COMP_VO. The logic gate 708 has a first input coupled to the output of the inverter 702, a second input coupled to the output of the comparator 502, and a third input coupled to the output of the comparator 618. The logic gate 708 provides an output signal that may be first state (e.g., a logic high) if TEST-EN is a logic high, COMP_VI is a logic high, and COMP_VO is a logic low. The output of the logic gate 708 is coupled to the flip-flop 710. The flip-flop 710 has a first input (e.g., a set input) coupled to the output of the logic gate 708. The flip-flop 710 has a second input(e.g., a reset input) coupled to the output of the logic gate 706. The flip-flop 710 has an output coupled to the flip-flop 712.

The flip-flop 712 has a first input (e.g., a data input) coupled to the output of the flip-flop 710, a second input (e.g., a clock input) coupled to the output of the inverter 702, and a third input (e.g., a set input) coupled to the output of the buffer 622. The flip-flop 712 has an output at which a fault signal FAIL_Z is provided. The output of the 712 is coupled to If VO_VALID indicates that the voltage at VOUT is not within the selected range, then FAIL_Z has a state (e.g., a logic low state) indicating that the switching converter 300 (or the switching converter 350) has a fault, and may not be able to deenergize the brake relay 224. If, at the rising edge of TEST_EN, the voltage at VOUT is within the selected range, then the state of FAIL_Z is determined by the output signal of the flip-flop 710.

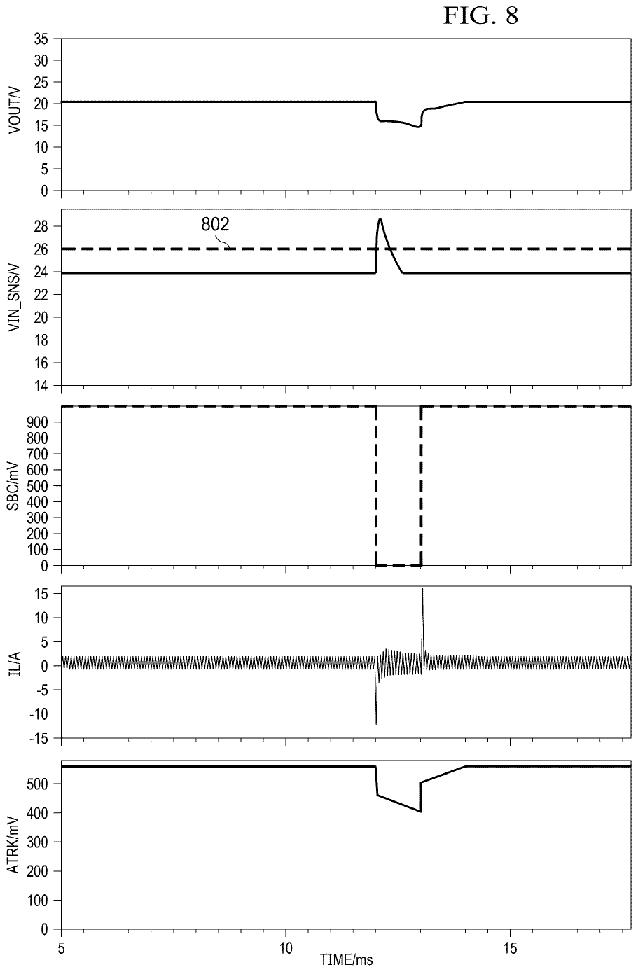

FIG. 8 is a graph of example signals in the switching converter 300 showing periodic testing with no fault in the switching converter 300. FIG. 8 shows the voltage at VOUT, the signal VIN_SNS, the signal SBC, the current in the inductor 332 (IL), and the signal ATRK. The differential threshold created by the voltage source 504 is shown as voltage 802. Prior to the SBC pulse, the switching converter 300 is operating in steady state, and the voltage at VOUT is within the selected range. Responsive to the SBC pulse, ATRK causes the controller 316 to set the switches 306, 308, 310, and 312 to transfer charge from the capacitor 314 to the capacitor 304. IL shows negative current flow responsive to the falling edge of ATRK, and the voltage at the first terminal of the switch 306 rises to exceed the voltage 802, showing that the switch 306 is functioning. The voltage at VOUT is reduced by the reverse current.

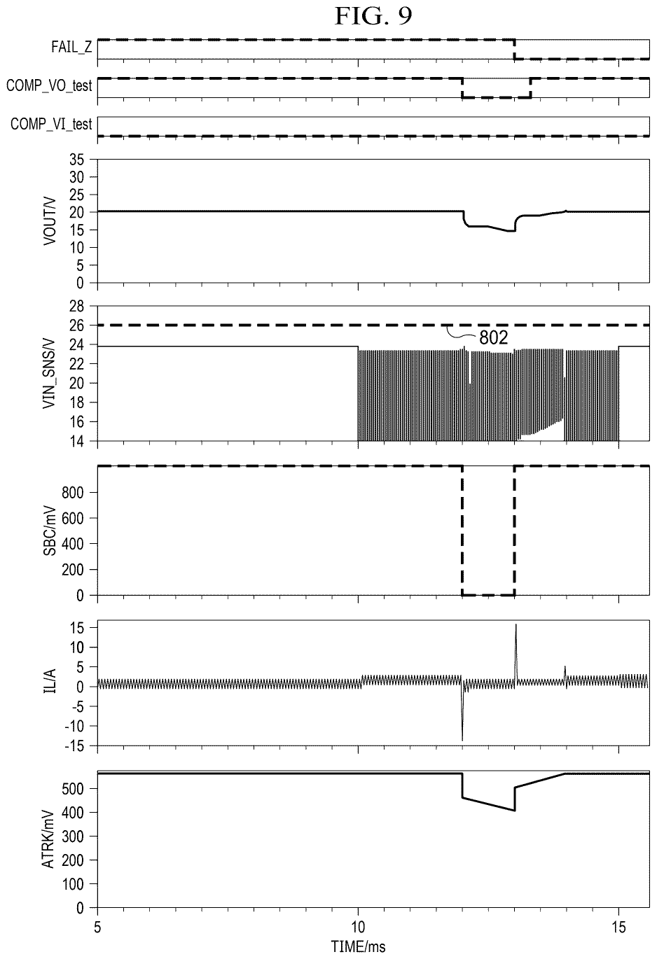

FIG. 9 is a graph of example signals in the switching converter 300 showing periodic testing with a fault in the switching converter 300. FIG. 9 shows the voltage at VOUT, the signal VIN_SNS, the signal SBC, the current in the inductor 332 (IL), and the signal ATRK. The differential threshold created by the voltage source 504 is shown as voltage 802. FAIL_Z, COMP_VO, and COMP_VI are also shown. In the example of FIG. 9, there is a short circuit between the first and second terminals of the switch 306.

Responsive to the SBC pulse, ATRK causes the controller 316 to set the switches 306, 308, 310, and 312 to transfer charge from the capacitor 314 to the capacitor 304. IL shows negative current flow responsive to the falling edge of ATRK. Because of the short, the voltage at the first terminal of the switch 306 does not exceed the voltage 802, showing that the switch 306 is faulty. COMP_VO indicates that the voltage at VOUT is within the selected range, but COMP_VIN shows that the voltage across the diode 302 is too low. FAIL_Z is set to a logic low at the trailing edge of SBC to indicate a fault in the switching converter 300.

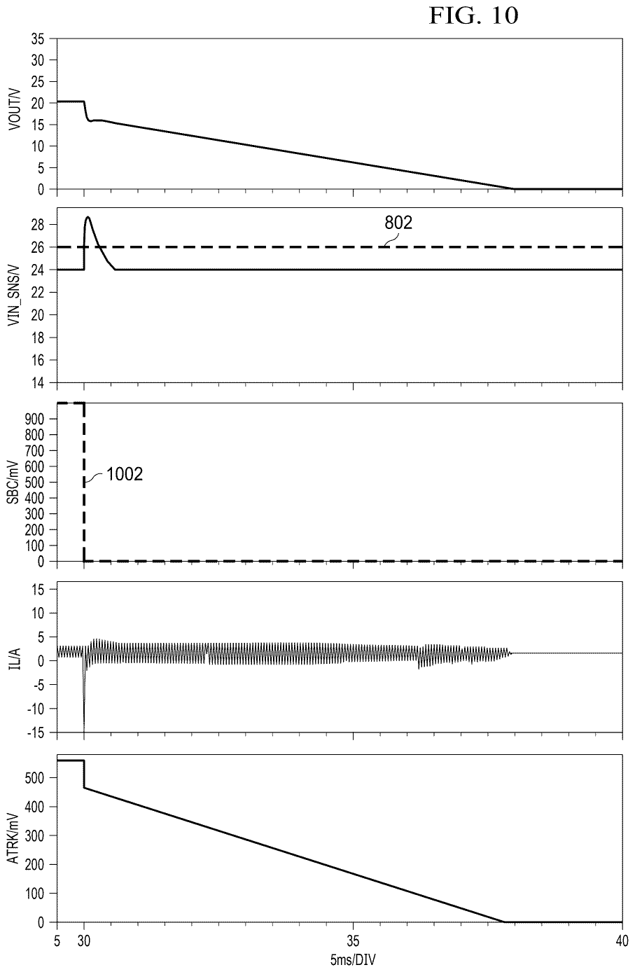

FIG. 10 is a graph of example signals in the switching converter 300 showing turn-off of the switching converter 300 to engage the brake. FIG. 10 shows the voltage at VOUT, the signal VIN_SNS, the signal SBC, the current in the inductor 332 (IL), and the signal ATRK. The differential threshold created by the voltage source 504 is shown as voltage 802. At time 1002, SBC transitions from logic high to logic low, and remains logic low. Responsive to SBC, ATRK causes the controller 316 to set the switches 306, 308, 310, and 312 to transfer charge from the capacitor 314 to the capacitor 304. IL shows negative current flow responsive to the falling edge of ATRK, and the voltage at the first terminal of the switch 306 rises to exceed the voltage 802, showing that the switch 306 is functioning. ATRK decreases to zero volts at time 1004, and regulates the voltage at VOUT to zero volts. The inductor 332 is deenergized, the current flow to the brake relay 224 is zero amperes. With no current flow to the brake relay 224, the brake is engaged.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a first switch having a first terminal coupled to a voltage input terminal, a second terminal coupled to a first inductor terminal, and a control terminal;
a second switch having a first terminal coupled to a second inductor terminal, a second terminal coupled to a voltage output terminal, and a control terminal;
a controller including:
a modulator having a first output coupled to the control terminal of the first switch, a second output coupled to the control terminal of the second switch, and an input;
an error amplifier having an output coupled to the input of the modulator, and an input; and
a brake control circuit having an output coupled to the input of the error amplifier, a first input coupled to a brake control terminal, a second input coupled to the voltage input terminal, and a third input coupled to the voltage output terminal.

2. The apparatus of claim 1, wherein:
the input of the error amplifier is a first input; and
the error amplifier includes a second input coupled to the voltage output terminal.

3. The apparatus of claim 1, wherein:
the input of the error amplifier is a first input; and
the controller includes a voltage reference circuit having an output; and
the error amplifier includes a second input coupled to the output of the voltage reference circuit.

4. The apparatus of claim 1, where the brake control circuit includes:
a transconductance amplifier having an input coupled to the brake control terminal, and an output coupled to the input of the error amplifier;
a buffer circuit having an input coupled to the input of the transconductance amplifier, and an output; and
a capacitor having a first terminal coupled to the output of the buffer circuit, and a second terminal coupled to the input of the error amplifier.

5. The apparatus of claim 1, wherein the brake control circuit includes:
a voltage reference circuit having an output;
a first resistor having a first terminal coupled to the second terminal of the second switch, and a second terminal;
a second resistor having a first terminal coupled to the second terminal of the first resistor, and a second terminal coupled to a reference terminal; and
a comparator having a first input coupled to the second terminal of the first resistor, a second input coupled to the output of the voltage reference circuit, and an output.

6. The apparatus of claim 5, wherein:
the comparator is a first comparator; and
the brake control circuit includes:
a third resistor having a first terminal coupled to the second terminal of the second switch, and a second terminal;
a fourth resistor having a first terminal coupled to the second terminal of the first resistor, and a second terminal coupled to the reference terminal;
a second comparator having a first input coupled to the output of the voltage reference circuit, a second input coupled to the second terminal of the third resistor, and an output; and
a logic gate having a first input coupled to the output of the first comparator, a second input coupled to the output of the second comparator, and an output.

7. The apparatus of claim 6, wherein the brake control circuit includes:
a fifth resistor having a first terminal coupled to the second terminal of the second switch, and a second terminal;
a sixth resistor having a first terminal coupled to the second terminal of the first resistor, and a second terminal coupled to the reference terminal; and
a third comparator having a first input coupled to the second terminal of the fifth resistor, a second input coupled to the output of the voltage reference circuit, and an output.

8. The apparatus of claim 7, wherein the brake control circuit includes a fourth comparator having a first input coupled to the voltage input terminal, a second input coupled to the first terminal of the first switch, and an output.

9. The apparatus of claim 8, wherein:
the logic gate is a first logic gate; and
the brake control circuit includes:
a second logic gate having a first input coupled to the brake control terminal, a second input coupled to the output of the fourth comparator, a third input coupled to the output of the third comparator, and an output;
a monostable circuit having an input coupled to the brake control terminal, and an output;
a first flip-flop having a first input coupled to the output of the second logic gate, a second input coupled to the output of the monostable circuit, and an output; and
a second flip-flop having a first input coupled to the output of the first flip-flop, a second input coupled to the brake control terminal, a third input coupled to the output of the first logic gate, and an output coupled to a fault terminal.

10. An apparatus comprising:
a high-side switch having a first terminal coupled to a voltage terminal, a second terminal, and a control terminal;
a switching control circuit having a high-side switch output; and
a logic gate having a first input coupled to the high-side switch output, a second input coupled to a brake control terminal, and an output coupled to the control terminal of the high-side switch.

11. The apparatus of claim 10, wherein:
the logic gate is a first logic gate; and
the apparatus includes a fault detection circuit comprising:
a comparator having a first input coupled to the second terminal of the high-side switch, a second input coupled to a reference circuit, and an output; and
a second logic gate having a first terminal coupled to the second input of the first logic gate, a second input coupled to the output of the comparator, and an output coupled to a fault terminal.

12. The apparatus of claim 11 wherein:
the first logic gate is an and gate; and
the second logic gate is an exclusive-or gate.

13. The apparatus of claim 10, wherein:
the switching control circuit has an input; and
the apparatus includes:
a low-side switch having a first terminal coupled to the second terminal of the high-side switch, and a second terminal coupled to a reference terminal; and
an inductor having a first terminal coupled to the second terminal of the high-side switch, and a second terminal coupled to the input of the switching control circuit.

14. The apparatus of claim 13, further comprising a brake relay coupled to the second terminal of the inductor.

15. A switching converter comprising:
a brake control terminal configured to receive a brake control signal;
a switch having a first terminal, a second terminal, and a control terminal, the switch configured to conduct a current between the first terminal and the second terminal responsive to a control signal received at the control terminal;
a controller having an input coupled to the brake control terminal, and an output coupled to the control terminal of the switch, the controller configured to control the switch responsive to the brake control signal; and
a brake control circuit having a first input coupled to the second terminal of the switch, a second input coupled to the brake control terminal, and an output, the brake control circuit configured to:
compare a voltage at the second terminal of the switch to a threshold responsive to the brake control signal; and
provide a fault signal at the output of the brake control circuit, the fault signal indicating that the voltage at the second terminal of the switch exceeds the threshold responsive to the brake control signal.

16. The switching converter of claim 15, wherein the brake control circuit includes a logic gate having a first input coupled to the brake control terminal, a second terminal coupled to an output of a modulator, and an output coupled to the control terminal of the switch.

17. The switching converter of claim 16, wherein the brake control circuit includes:
a comparator having a first input coupled to the second terminal of the switch, a second terminal coupled to a voltage reference circuit, and an output; and
a logic gate having a first input coupled to the brake control terminal, a second input coupled to the output of the comparator, and an output coupled to the output of the brake control circuit.

18. The switching converter of claim 15, further comprising:
an input terminal configured to receive an input voltage;
a diode having a cathode coupled to the first terminal of the switch, and an anode coupled to the input terminal;
wherein the controller includes:
a modulator having a first output coupled to the control terminal of the switch, and an input;
an error amplifier having an output coupled to the input of the modulator, and an input;
a transconductance amplifier having an output coupled to the input of the error amplifier, and an input coupled to a brake control terminal;
a buffer circuit having an input coupled to the input of the transconductance amplifier, and an output;
a capacitor having a first terminal coupled to the output of the buffer circuit, and a second terminal coupled to the input of the error amplifier; and
a comparator having a first input coupled to the cathode, a second input coupled to the anode, and an output.

19. The switching converter of claim 18, wherein:
the comparator is a first comparator; and
the brake control circuit includes:
a second comparator configured to determine whether the voltage at the second terminal of the switch is greater than a first threshold;
a third comparator configured to determine whether the voltage at the second terminal of the switch is less than a second threshold;
a fourth comparator configured to determine whether the voltage at the second terminal of the switch is greater than a third threshold; and
a logic gate having a first input coupled to an output of the second comparator, a second input coupled to an output of the third comparator, and an output.

20. The switching converter of claim 19, wherein:
the logic gate is a first logic gate; and
the brake control circuit includes:
a second logic gate having a first input coupled to the input of the transconductance amplifier, a second input coupled to the output of the fourth comparator, a third input coupled to the output of the third comparator, and an output;
a monostable circuit having an input coupled to the input of the transconductance amplifier, and an output;
a first flip-flop having a first input coupled to the output of the second logic gate, a second input coupled to the output of the monostable circuit, and an output; and
a second flip-flop having a first input coupled to the output of the first flip-flop, a second input coupled to the input of the monostable circuit, a third input coupled to the output of the first logic gate, and an output coupled to the output of the brake control circuit.
